(19) United States
(12) Patent Application Publication
(10) Pub. No.: US 2005/0269285 A1
(43) Pub. Date: Dec. 8, 2005

(54) Method for fabricating a nanopattern and a carbon nanotube bio-nanoarray using the self-assembly of supramolecules and UV etching

(76) Inventors: Hee Tae Jung, Daejeon (KR); Dae Hwan Jung, Daejeon (KR); Young Koan Ko, Daejeon (KR); Ki Young Kwon, Pohang-si (KR); Su Rim Lee, Yangyang-gun (KR)

Correspondence Address: INTELLECTUAL PROPERTY / TECHNOLOGY LAW, PO BOX 14329, RESEARCH TRIANGLE PARK, NC, 27709, US

(21) Appl. No.: 10/859,529

(22) Filed: Jun. 2, 2004

(30) Foreign Application Priority Data
Jun. 12, 2003 (KR) 10-2003-0037752

(51) Int. Cl. C23F 1/00; G03F 7/00

(52) U.S. Cl. 216/8; 216/58

(57) ABSTRACT

A method for forming a groove-shaped nanopattern, which involves the steps of forming a thin film of supramolecules on a substrate, inducing the self-assembly of the supramolecules by annealing to form regular structures, and applying UV to the formed regular structures of supramolecules. A method for fabricating a CNT nanoarray is also described, which includes the step of forming a regular metal catalyst array for synthesizing CNT using a formed nanopattern of supramolecules as a mask, and then synthesizing CNT vertically. In another aspect, a method is described for fabricating a CNT-bionanoarray, which involves attaching a bioreceptor to the fabricated CNT array.

### CROSS-REFERENCE TO RELATED APPLICATION

This application claims priority under 35 USC 119 of Korean Patent Application No. 10-2003-0037752 filed Jun. 12, 2003.

### BACKGROUND OF THE INVENTION

1. Field of the Invention

The present invention relates to a method for forming several nanometer- or smaller sized regular pattern using self-assembly of supramolecule and UV etching; to a method for fabricating CNT(carbon nanotube) array, which comprises the steps of fabricating metal catalyst array by lift-off method using the formed nanopattern as a mask, and synthesizing CNT vertically using the metal catalyst array; and also to a method for fabricating CNT-bio nanoarray, which comprises the step of attaching bioreceptor to the fabricated CNT array.

2. Background of the Related Art

Formerly, surface pattern formation has been achieved by photolithography using a polymeric thin film as photoresist, but the realization of a nanometer-sized, highly precise pattern by this method encounters many difficulties, because of limitations in the wavelength of light capable of being used and the necessity for provision of an apparatus and technology suitable for such light wavelength, as well as issues relating to the resolution of the polymer itself.

Since the year 1990, there have been attempts to use new photoresists in photolithography and to increase the resolution of pattern using light of a shorter wavelength. Furthermore, patterning techniques of a completely new concept, such as nanopatterning techniques using soft lithography, started to appear. Such techniques have advantages in that they allow inexpensive patterning and continuous operations. However, their resolution limit is a level of about 100 nm and it is difficult to expect a further increase in resolution leading to an increase in integration density.

Meanwhile, Korean patent No. KR 10/263671B1 discloses a method for forming nanometer-sized fine patterns using supramolecules as a patterning material. In this method, the thickness of fine pattern remaining in a groove is ensured using one additional buffer layer in order to ensure a margin for excessive etching, and a spacer is also formed on the buffer layer in order to reduce the size of the groove. However, the number of process steps is large, and the pattern size is a level of several tens of nanometers.

Korean patent publication No. KR 2002-0089528A discloses a small-sized, self-assembled structure for forming devices that are widely used in the microelectronic industry. The self-assembly method disclosed in this application provides the ability to form arrays in association with a surface, but it is impossible for the self-assembly itself to determine the position of a device-forming material within the boundary along the surface. Thus, in forming a device within the boundary along the surface, an individual positioning technique is necessary, and a suitable positioning technique is used with the self-assembly method, to form a structure capable of functioning as an individual part in integrated electronic circuits. The positioning technique permits one to determine the boundary of a structure by lithography, direct formation methods or other positioning techniques, so that a patterned substrate is formed and a device is assembled on the substrate by self-assembly.

A self-assembled structure can be combined with a structure formed by the conventional chemical or physical deposition technique, and an integrated electronic circuit can comprise integrated optical parts. The self-assembled structure can be formed using nanoparticle dispersion in such a manner that the desired structure is obtained by adjustment according to a material surface state and temperature and concentration conditions. A linker, one end of which is bound to the substrate surface and the other end of which is chemically bound to nanoparticles, is used, and selective binding using the linker can be used to yield a self-assembly process of nanoparticles.

Another selective binding method is to use natural interaction, such as electrostatic and chemical interaction, to perform the self-assembly process of nanoparticles, in which the nanoparticles are deposited in micropores such that they are positioned within the boundary defined by porous regions. The micropores can be found in certain materials, such as inorganic oxides or two-dimensional organic crystals, or suitable micropores can be formed by, for example, ion milling or chemical etching. However, this method is disadvantage in that the process is complex, and a spacing between pattern remains at a level of several tens to hundreds of nanometers.

Furthermore, Korean patent publication No. 2003-0023191A discloses a method for forming a nanometer-sized ultrafine pattern using a self-assembled monomolecular layer. This method comprises the steps of forming a layer of aromatic imine molecules with substituted end groups on a substrate, selectively binding and cutting the substituent groups of the aromatic imine molecule layer, and hydrolyzing the resulting aromatic imine molecule layer, thereby enabling the pattern to be formed in a short time. However, the pattern size according to this method still remains at a level of several tens of nanometers.

Meanwhile, dip-pen nanolithography was reported in which the tip of an atomic force microscope is stained with surfactant molecules having a chemical affinity for a solid substrate, and nanofeatures are formed on the substrate, much like the tip of a pen would write with ink on paper (Piner, R. D. et al., Science, 283:661, 1999). This technique has an advantage in that it is possible to achieve a high-resolution pattern as small as 5 nm in special resolutions using an ultra-sharp tip. However, this technique has a problem in that the pattern must be separately formed in a serial processing manner, so that a long time is required to achieve the desired features, thus making it difficult to directly apply this technique to mass production.

As described above, although various methods, including photolithography and etching methods using ultraviolet light and X-ray, are being introduced, the formation of sub-100 nm patterns has reached intrinsic limitations. In an attempt to resolve this issue, bottom-up methods are being widely studied as a substitute for the existing top-down methods.

The bottom-up methods are based on the formation of microstructures by the self-assembly of molecules, and among such basic technologies, a method of analyzing the microstructure of supramolecules by a scanning electronic microscope has been reported (Hudson, S. D. et al., Science, 278:449, 1997) and it has been reported that the orientation of supramolecules varies depending on the surface property of a substrate (Jung, H. T. et al., Macromolecules, 35:3717, 2002). However, these publications describe only the microstructure analysis of supramolecules and the orientation of supramolecules, respectively.

Studies are being conducted on forming sub-100 nm patterns using block copolymers, e.g., involving the formation of regular patterns using block copolymers and the formation of dot-shaped patterns using metal staining (Park, M. et al., Science, 276:1401, 1997). However, the patterns formed by such methods remain at a level of several tens of nanometers or larger size, since they rely on the molecular chain of the polymers. Also, the use of the block copolymers has problems in that the aspect ratio of the pattern formed is not large, the structure of a thin film is complex, and it is difficult to give an orientation to the structure of the thin film.

Because of their properties of excellent structural rigidity, chemical stability, ability to act as ideal one-dimensional (1D) “quantum wires” with either semiconducting or metallic behaviors, a large aspect ratio, and empty interior, CNTs exhibit a broad range of potential applications as a basic material of flat panel displays, transistors, energy reservoirs, etc., and as various sensors with nanosize.

The CNT synthesis using known methods of CVD synthesis involves first depositing Fe, Ni, Co or the alloy of these three metals as a metal catalyst on a substrate, etching the deposited substrate with water-diluted HF, mounting the sample on a quartz boat, and then after inserting the quartz boat into the reactor of a CVD device, additionally etching the metal catalyst film using NH₃ gas at 750˜1050° C. to form fine metal catalyst particles with nanosize. Since the CNT is synthesized on the fine metal catalyst particles, forming the fine metal catalyst particles is an important process in the CVD synthesis method. However, there is no report of a technology arranging a regular metal catalyst of several nanometers in a patterned form at regular intervals, even though forming a nanosize metal catalyst particle is a very important process. CNT that is vertically synthesized maintaining regular intervals using the formed metal catalyst array will show excellent material properties, compared to conventional synthesized CNT structure with no intervals.

As a solution to such problems, the growth of CNT on a nickel catalyst array fabricated by using e-beam lithography has been reported (Li, J. et al., Nano Letter, 3:597, 2003). However, such approach has many limitations in application to large size substrates and mass-production.

Meanwhile, microarray protein chips are of high importance in current researches on diagnostic proteomics. An early array technology (U.S. Pat. No. 5,143,854) that utilized a photolithographic technique in fabricating a polypeptide array on the surface of a substrate has recently been the subject of renewed attention. In particular, the importance of development of a microarray-type format in various immunoassays, including antigen-antibody pairs and enzyme-liked immunosorbent assays, is gradually increasing.

However, it is difficult to make the protein array smaller than a DNA array or to integrate or arrange the protein array into a substantial format with improved sensitivity. The lattice pattern of DNA oligonucleotides can be produced on the surface of a substrate by photolithography, but in the case of a protein consisting of several hundreds of amino acids, more highly integrated lattice patterns with high density (for example, an antibody can have about 1,400 amino acids) are required in order to achieve precise diagnosis of diseases on the substrate surface. This requirement, however, is not easily satisfied.

Another problem is that the three-dimensional structure of proteins can be easily broken during their manipulation under denaturing conditions (Bernard, A. et al., Anal. Chem., 73:8, 2001), yet another of the many difficulties involved in manipulating proteins.

A solution to such problems requires proteins to be arrayed at high resolution without loss of their three-dimensional structure. Various approaches, including inkjet printing, drop-on-demand technology, microcontact printing, and soft lithography, have been proposed to resolve these problems. However, arrays formed by such methods also have a spacing of several tens of micrometers to several millimeters, and to date, no high-precision diagnostic protein nanoarrays have been developed that accommodate real-life samples integrated with high density while maintaining the three-dimensional structure of the protein.

Recently, researches have been conducted to detect both protein-protein and protein-ligand reactions by means of electrochemical changes of CNT after immobilization of a biomaterial (Dai, H. et al., ACC. Chem. Res., 35:1035, 2002; Sotiropoulou, S. et al., Anal. Bioanal. Chem., 375:103, 2003; Erlanger, B. F. et al., Nano Lett., 1:465, 2001; Azamian, B. R. et al., JACS, 124:12664, 2002).

The reasons that CNT attracts public attention as a biochip material and technique include the following: firstly, CNT needs no labeling; secondly, CNT has high sensitivity to electric or electrochemical signal change; and thirdly, CNT is capable of reacting in an aqueous solution without deterioration of a protein because it has chemical functional groups. The application of biological systems to CNT as a well-arranged and new nanomaterial, will create important fusion technologies in various fields, including for example disease diagnosis (hereditary diseases), proteomics and nanobiotechnology.

Many applications of CNT in the bioengineering field have recently appeared. Applications of CNT to biochips, for applications such as glucose biosensors, detection of protein, detection of a specific DNA sequence, and the like, have been proposed (Sotiropoulou, S. et al., Anal. Bioanal. Chem., 375:103, 2003; Chen, R. J. et al., Proc. Natl. Acad. Sci. USA, 100:4984, 2003; Cai, H. et al., Anal. Bioanal. Chem., 375:287, 2003). At the present time, the most universal method for detecting the result of a reaction in a biochip is to use conventional fluorescent materials and isotopes (Toriba, A. et al., Biomed. Chromatogr., 17:126, 2003; Syrzycka, M et al., Anal. Chim. Acta, 484:1, 2003; Rouse, J. H. et al., Nano Lett., 3:59, 2003). However, as novel methods to easily and precisely measure an electrical or electrochemical signal are attempted, there are increased demands for CNT as a new material.

The methods of preparing a high density CNT multiplayer, attaching DNA thereon and detecting complementary DNA, are useful in genotyping, mutation detection, pathogen identification and the like. PNA (peptide nucleic acid: DNA mimic) that is regio-specifically fixed on a single walled CNT and its complementary binding to probe DNA, have been reported (Williams, K. A. et al., Nature, 420:761, 2001). Also, the fixing of an oligonucleotide on a CNT array by a electrochemical method and its use to detect DNA by guanine oxidation has been reported (Li, J. et al., Nano Lett., 3:597, 2003). These methods, however, do not apply CNT to the fabrication and development of biochips.

Recently, a high capacity biomolecule detection sensor using CNT has been disclosed (WO 03/016901 A1). This patent publication describes a multi-channel type biochip produced by arranging a plurality of CNTs on a substrate using a chemical linker and attaching various types of receptors. However, this structure has the substantial disadvantage of relative weakness to environmental changes.

### SUMMARY OF THE INVENTION

Accordingly, the present inventors have conducted intensive studies to develop a simpler method for forming a several nanometer-sized ultrahigh density pattern on a substrate with a large surface area. In the course of this work, the inventors discovered the approach of forming patterns of several nanometers or smaller in size using supramolecular self-assembly and UV etching, and fabricating CNT-bio nanoarrays by regularly arranging a metal catalyst and using the formed pattern as a mask to attach bioreceptors to the CNT array arranged regularly on the substrate.

The invention in one aspect provides a method for forming nanometer- or smaller sized patterns of supramolecules using self-assembly of supramolecules and UV etching.

The invention in another aspect provides a method for forming a nanopattern on a substrate or a intermediate thin film on the substrate, which comprises the step of etching the substrate or the intermediate thin film using a nanopattern of supramolecules as a mask.

In yet another aspect, the invention provides a method for forming a nanoarray or nanopattern of metal compounds on a substrate by performing a lift-off process after depositing metal compounds using a nanopattern of supramolecules as a mask.

In a further aspect, the invention provides a method for forming nanoarray or nanopattern of metal catalyst selected from the group consisting of Fe, Ni, Co, and alloys thereof, using a nanopattern of supramolecules as a mask.

A further aspect of the invention relates to a method for fabricating a CNT array, which comprises synthesizing CNT vertically on a metal catalyst nanopattem formed by the above method.

Yet another aspect of the invention relates to a method for fabricating a CNT-bio nanoarray, which comprises attaching biomaterial binding bioreceptor to a CNT array fabricated by the above method.

Other aspects, features and embodiments of the invention will be more fully apparent from the ensuing disclosure and appended claims.

### BRIEF DESCRIPTION OF THE DRAWINGS

FIG. 1 schematically shows a method for forming metal catalyst nanopattern by using self-assembling supramolecules. FIG. 1a shows that disc-shaped dendrimers (1) and fan-shaped supramolecules (2) are self-assembled into cylindrical structures (3) which are then arranged into three-dimensional hexagonal structures (4). FIG. 1b shows stick-chain shaped or cone-shaped molecules (5) are self-assembled into hexagonal pillar-shaped structure (6), and the pillars are gathered to be arranged into a three-dimensional regular structure (7).

FIG. 2 schematically shows a process of fabricating metal catalyst array by performing a lift-off process after forming a nanopattern using self-assembly of supramolecules and UV etching, and depositing metal catalysts according to the present invention.

FIG. 3 is a schematic diagram showing a process of the fabrication of CNT-bio nanoarray, which comprises the steps of synthesizing CNT on the metal catalyst array fabricated by the method of FIG. 2, opening the capping of the synthesized CNT ends by plasma treatment, and then chemically binding biomaterials to the CNT ends.

FIG. 4 is a transmission electron microscope photograph showing that supramolecules are formed regular structures.

### DETAILED DESCRIPTION OF THE INVENTION, AND PREFERRED EMBODIMENT THEREOF

The present invention provides a method for forming nanometer- or smaller sized patterns, which comprises the steps of: (a) forming a thin film of supramolecules inducing self-assembly on a substrate; (b) self-assembling the supramolecules by annealing to form a cylindrical shaped regular structure; and (c) applying UV to the cylindrical shaped structure formed by self-assembly of the supramolecules and then decomposing the central part in which carbon chains are gathered, thereby forming hole shaped nanopattern of supramolecules.

The present invention also provides a method for fabricating carbon nanotubes (CNT) nanoarrays, which comprises the steps of: (a) forming a thin film layer of metal catalyst, selected from the group consisting of Fe, Ni, Co, and alloys thereof, for growing CNT vertically on the nanopattern of supramolecules formed by the above method; (b) performing a lift-off process using a solvent which is capable of dissolving the supramolecules; (c) forming a metal catalyst array by removing residues after lift-off process; and (d) synthesizing CNT vertically on the formed metal catalyst array.

In one embodiment of the present invention, an additional step of introducing carboxyl group by plasma treatment on the CNT array end that is arranged vertically, can be performed. After the carboxyl group is exposed on the end of the CNT array by plasma treatment, various bioreceptors can be chemically bound to the CNT array.

In another aspect, the present invention provides a method for fabricating a CNT-bio nanoarray, characterized in that a bioreceptor selected from the group consisting of proteins, peptides, amino acids, DNA, PNA, enzymatic substrates, ligands, cofactors, carbohydrates, lipids, oligonucleotides, and RNA are attached to the CNT array fabricated by the above method.

In this method, the step of attaching the bioreceptor to CNTs can be performed in any suitable manner, e.g., by applying a charge of a polarity opposite to the net charge of the bioreceptor to the CNTs (KR 2003-0014997A), or by using a binding aid. The binding aid preferably includes a chemical substance having an aldehyde, amine or imine group attached to a carbon group end.

The present invention in a further aspect provides a method for fabricating a CNT-bio nanoarray which involves binding a bioreceptor having an amine group (NH₂) to the CNT array on the end of which carboxyl group functionality is exposed, by formation of an amide bond. It is generally preferred to use a coupling agent and a coupling aid for inducing amide bond formation in such methodology.

In the practice of the invention described hereinabove, the thin film in step (a) preferably is formed by spin-coating, rubbing, or solution spreading, which forms a thin film on the surface of water, and the annealing in the above step (b) preferably is performed by heating the supramolecules above their liquid crystal phase transition temperature and then cooling them slowly.

In yet another aspect, the present invention provides a method for fabricating a nanopattern of magnetic metal thin film for providing a recording material with high density, which comprises the steps of: (a) forming a thin film of supramolecules inducing self-assembly on a substrate; (b) self-assembling the supramolecules by annealing to form a cylindrical shaped regular structure; (c) applying UV to the cylindrical shaped regular structure formed by self-assembly of the supramolecules and then decomposing the central part in which carbon chains are gathered; (d) forming a magnetic metal thin layer on the pattern of supramolecules; (e) performing a lift-off process using a solvent which is capable of dissolving the pattern of supramolecules; and (f) removing residues after lift-off process. In this method, the magnetic metal is preferably selected from the group consisting of Fe, Ni, Co, Cr, Pt, and alloys thereof.

In one embodiment of the present invention, a compound of the following formula (6) or formula (7) is used as the supramolecules, but any self-assembling supramolecules may alternatively be used. Examples of self-assembling supramolecules include round plate-shaped or disc-shaped dendrimers (1), fan-shaped supramolecules (2), stick-chain shaped or cone-shaped molecules (5). An example of the fan-shaped supramolecules includes a compound of the following formula (6) or formula (7), an example of the round plate shaped supramolecules includes a compound of the following formula (8), and an example of the cone-shaped supramolecules includes a compound of the following formula (9):

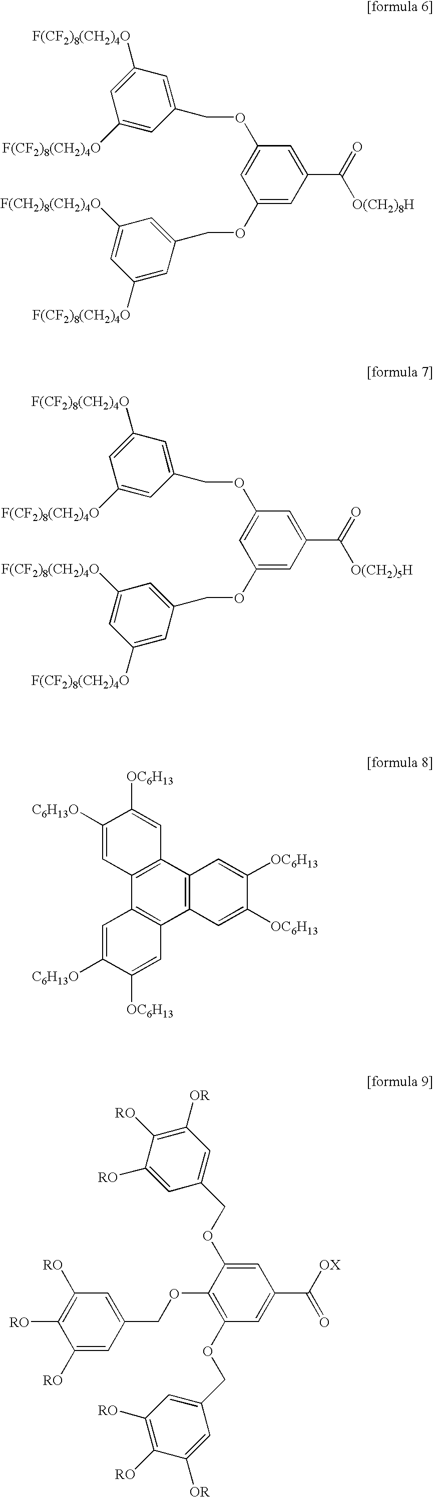

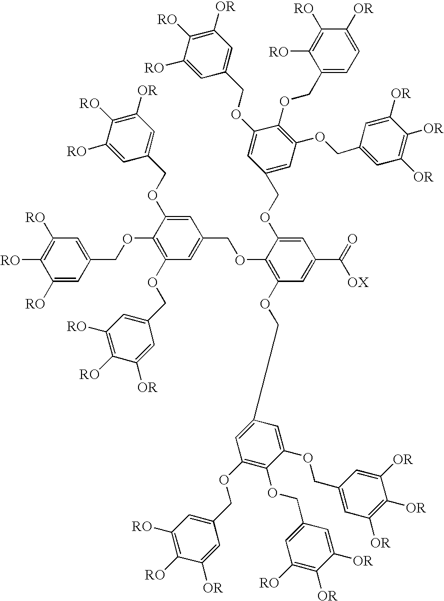

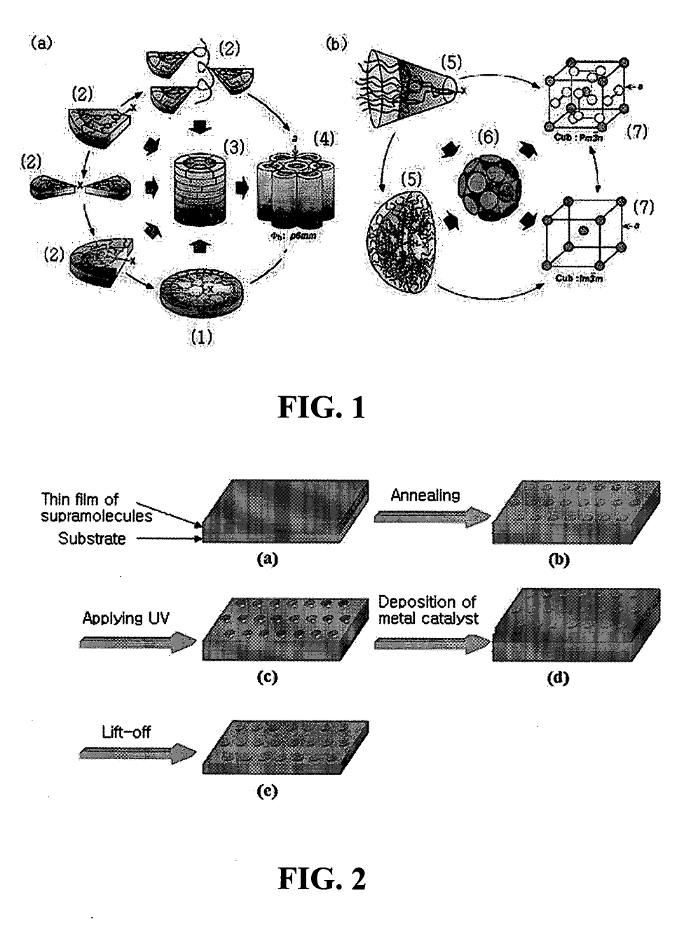

Such supramolecules are formed into a regular structure by physical secondary binding, such as van der Waals forces, unlike polymers in which monomers are covalently bonded. Such supramolecules are self-assembled by suitable temperature or concentration, external magnetic field or electric field, etc, to form certain fine structures. As shown in FIG. 1a, such fan-shaped dendrimers are self-assembled into plate-shaped structures (1), which are then assembled into pillar-shaped structures (3), which are formed into a three-dimensional hexagonal structure (4). In addition, as shown in FIG. 1b, the cone-shaped supramolecules (5) are self-assembled into spheres (6), which are then arranged into a three-dimensional regular structure (7).

The present invention also provides a method for forming nanopattern on a substrate, which comprises the step of etching the substrate using the nanopattern of supramolecules formed by the above method as a mask. In the present invention, etching the substrate is preferably performed by reactive ion etching and/or ion milling.

Further, the present invention provides a method for fabricating a bio nanoarray, which comprises the step of attaching a bioreceptor to a. groove-shaped substrate nanopattern fabricated by the above method.

In the step of attaching bioreceptors to the nanopattern of the present invention, bioreceptors can be attached after chemical functional groups are provided to the nanopattern of a substrate, e.g., using silanization of the silanes, when a silanol group (Si—OH) is present on the substrate. For example, the chemical in which aldehyde, carboxyl, amine or imine group is bound to the ethoxyl-silane end is used to chemically bind the bioreceptors on the substrate surface.

In the step of attaching bioreceptors to the nanopattern of the present invention, bioreceptors can be attached after chemical functional group are provided to the nanopattern of a substrate by forming a self assembly monolayer (SAM) of chemicals having thiol functional group, when the substrate surface is treated with gold. For example, bioreceptors can be chemically bound to the substrate surface using the chemicals in which aldehyde, carboxyl, amine or imine group is bound on the SAM surface.

In the present invention, the method for forming CNT using metal catalyst can be performed by conventional CNT growth methods known in the art. C₂H₂, CH₄, C₂H₄, C₂H₆ or CO gas is used as reacting gas, and CNTs are grown vertically by methods such as plasma chemical vapor deposition, thermal chemical vapor deposition, etc. In the case of forming CNT using the metal catalyst nanopattem, CNT with very small diameter, below 10 nm per pattern, can be provided.

In another aspect, the present invention provides a method for fabricating a CNT-bio nanoarray, characterized in that a bioreceptor selected from the group consisting of proteins, peptides, amino acids, DNA, PNA, enzymatic substrates, ligands, cofactors, carbohydrates, lipids, oligonucleotides, and RNA, is attached to the CNT array fabricated by the above method.

In the present invention, a biomaterial binding bioreceptor is preferably selected from the group consisting of proteins, peptides, amino acids, DNA, PNA, enzymatic substrates, ligands, cofactors, carbohydrates, lipids, oligonucleotides, and RNA.

The bioreceptors, such as proteins, peptides and amino acids, possess respective intrinsic isoelectric points, and have a net charge with a neutral ion, cation or anion according to the ion intensity or pH of solution. Additionally, by adjusting the condition of solution to adjust the electrostatic interaction and hydrophobic interaction between such bioreceptors and CNTs with a certain charge, the same or different kinds of bioreceptors can be moved or arranged on the desired positions of a chip.

According to the present invention, a protein-specific receptor that binds selectively to a target protein involved in diseases can be attached selectively to the CNT nanoarray on one chip by applying an electric field. Also, the bioreceptor that can interact with various target proteins involved in various diseases can be attached selectively to CNTs by applying to the CNTs electric fields of different polarities from each other. Accordingly, it is possible to diagnose a variety of diseases on one chip in one step at large amounts in a rapid manner.

As used herein, the term “CNT bio-nanoarray” is defined to include biochips and biosensors, in which a bioreceptor that binds to or reacts with a biomaterial is attached to CNT nanopattern.

The present invention is described in greater detail hereinbelow.

According to a preferred embodiment of the present invention, supramolecules of formula (6) or formula (7) are first dissolved in a tetrahydrofuran (THF) solvent at a 1-wt % concentration, and the resulting solution is applied on a substrate to form a thin film of supramolecules. In forming the thin film of supramolecules, spin-coating, rubbing, or solution spreading, which forms a thin film on the water surface, preferably is used. In this embodiment, a silicon wafer is used as a substrate, and the modification of the substrate surface is not carried out (FIG. 2a).

Thereafter, the supramolecules are heated above their liquid crystal phase transition temperature such that they are self-assembled. Since the supramolecules used to illustrate the present invention have a liquid crystal phase transition temperature of about 30° C., they are heated to 70° C. and then cooled slowly for enough transition (FIG. 2b).

A hole shaped pattern is formed by applying UV to the fine structure of the formed cylindrical shaped supramolecules to decompose the central part of the above cylindrical structure (FIG. 2c).

A regular metal catalyst array is fabricated using the lift-off process after depositing the metal catalyst such as Fe, Co, Ni or an alloy thereof on the pattern of the supramolecules (FIG. 2d, FIG. 2e).

CNT can be synthesized by any suitable ones of known methods in the art using the fabricated metal catalyst array. In one illustrative method, C₂H₂, CH₄, C₂H₄, C₂H₆, or CO gas is used as reacting gas, and plasma chemical vapor deposition, thermal chemical vapor deposition, etc. is used to grow CNT vertically. If CNT is formed by metal catalyst nanopattern, CNT having very small diameter can be formed, since the diameter of one pattern is below 10 nm.

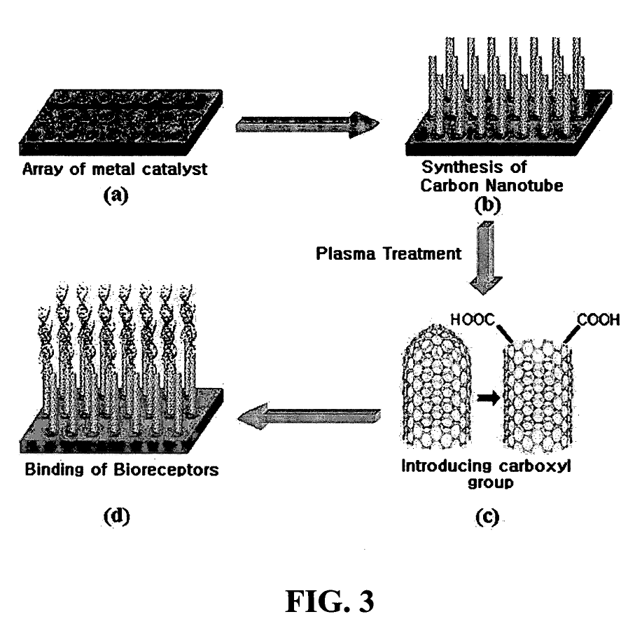

The present invention also includes a process of introducing carboxyl group functionality to the vertically grown CNT ends for binding biomaterials, by treating the CNT ends with plasma to open the end caps of the CNT (FIG. 3c).

The CNT nanoarray formed according to one preferred embodiment of the present invention as described above can be used as important surface substrates in forming a desired array by reacting various bioreceptors with the CNT nanoarray, and such nanoarrays will play a very important part in producing biochips of high integration density and small size.

Generally, the biochips are fabricated by linking biomolecules directly to a substrate or linking the bioreceptors to the substrate by means of linker molecules. For example, when bioreceptors (e.g., DNAs, antibodies or enzymes) must be attached to the surface of a solid substrate in order to produce DNA chips, protein chips or protein sensors, the desired bioarray can be fabricated by reacting a carboxyl group introduced to the CNT end with an amine group of the above biomaterial and fixing those to the CNT end by an amide bond.

A method for fabricating DNA chips incorporating a bio-nanoarray according to the present invention involves attaching a previously prepared probe to the surface of a solid substrate by a spotting method. In this case, an amine group-bound probe is dissolved in 1× to 7×, preferably 2× to 5×, and more preferably 3×SSC buffer solution (0.45M NaCl, 15mM C₆H₅Na₃O₇, pH 7.0), and then spotted to a carboxyl group exposed CNT end, by a microarrayer. Then, the probe is fixed to the CNT end by the reaction between aldehyde and amine. Here, the concentration of the probe is more than 10 pmol/μl, preferably more than 50 pmol/μl, and more preferably more than 100 pmol/μl. The amine group bound to the probe is advantageously reacted with the carboxyl group introduced to the CNT end at a humidity of 70-90%, and preferably 80%, for 4-8 hours, preferably 5-7 hours, and most preferably about 6 hours, so that the probe is fixed to the substrate. An amide coupling agent and EDC/NHS as an aid can be used in the method.

The self-assembly process of supramolecules by annealing according to a preferred embodiment of the present invention will now be described.

The properties of supramolecules can be modified by annealing, and starting materials suitable for annealing include supramolecules produced by pyrolysis. Also, the supramolecules used as the starting materials can undergo at least one preheating step under different conditions. The additional treatment in annealing the supramolecules formed by laser pyrolysis improves their crystallinity and removes contaminants such as atomic carbon, and possibly can change their stoichiometry by combining additional oxygen, or atoms from gaseous or nongaseous compounds. The supramolecules are preferably heated in an oven so as to provide uniform heating. The treatment conditions are generally mild so that a significant amount of sintered particles is not produced. Thus, the heating temperature preferably is lower than the melting point of both the starting material and the product. If the thermal treatment involves a change in composition, the size and shape of the molecules can be changed even at mild heating temperatures.

Self-assembled structures are formed on the surface of material/substrate or within the surface. The self-assembled structures are positioned within boundaries in the form of positioned islands, and each of the structures can serve as an element of circuits or devices having a plurality of elements. Particularly, each of the structures can be an element of integrated electronic circuits, and examples of this element include electrical parts, optical devices and photonic crystals.

In order to form a structure within a predetermined boundary, a process of defining the boundary of the structure and a separate self-assembly process are required for the formation of the self-assembled structure. The process of defining the boundary of the structure utilizes an external force in defining the structure boundary. It is generally impossible to define the structure boundary by the self-assembly process itself. When a composition/material is bound, its self-assembly is based on the natural sensing function of the composition/material, which causes natural ordering in the resulting structure.

Generally, although the positioning process can be conducted before or after the self-assembly process, the nature of treatment steps can also indicate certain orders. The net effect results in a self-assembled structure having a region within the boundary, which is covered with nanoparticles, and also a region outside the boundary, which is not covered with the nanoparticles. The process of defining the boundary is linked to the self-assembly process, by either activating the self-assembly process in the boundary or inactivating the region outside the boundary. Generally, to carry out the activating process or the inactivating process, the application of an external force is necessary.

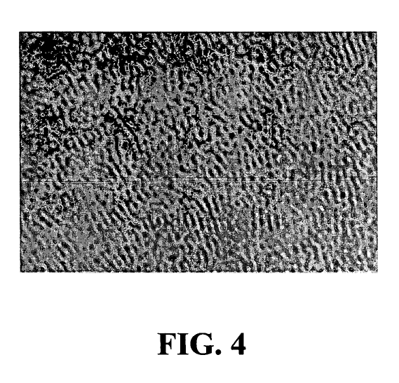

The fact that supramolecules are self-assembled into a regular structure on a substrate can be confirmed by a transmission electron microscope. A sample was fabricated under the same conditions as described herein, and a photograph of the sample taken by the transmission electron microscope is shown in FIG. 4. The photograph in FIG. 4 suggests that the supramolecules are self-assembled into hexagonal pillar-shaped regular structures.

### EXAMPLE

The present invention will hereinafter be described in further detail by examples. It will however be obvious to a person skilled in the art that these examples can be modified into various different forms and the present invention is not limited to or by the examples. These examples are presented to further illustrate the present invention.

### Example 1

### Synthesis of Supramolecules

The supramolecules of formula (6) and formula (7) used in the present invention were synthesized by a process consisting of 6 steps as shown in reaction scheme (1) below. In the first step, potassium carbonate acting a base to diform amide of 65° C. was resolved, and then methyl 3,5-dihydroxy benzoate and perfluorododecyl bromide were added to undergo refluxing for 8 hours. As a result, the compound of formula (1) was obtained by esterification.

The compound of formula (2) was obtained by reduction of the compound of formula (1) with tetrahydrofuran (THF) and lithium aluminium hydride at room temperature for 2 hours. The above compound was resolved in the mixed solution of dichloromethane and tetrahydrofuran and added by diform amide in a catalytic amount to undergo chlorination reaction for 20 minutes at room temperature by thionyl chloride. As a result, the compound of formula (3) was obtained.

The next step of esterification was performed as the first step. In the first step, methyl 3,5-dihydroxy benzoate and the compound of formula (3) were added to a mixed solution of potassium carbonate and diform amide to undergo refluxing for 18 hours at 65 □. As a result, the compound of formula (4) was obtained.

The compound of formula (5) was synthesized by hydrolysis of methyl ester which is caused by 10N potassium hydroxide, in the mixed solution of ethyl alcohol and THF. In the esterification, which is the final reaction, the compounds of formula (6) and (7) are synthesized by the same method in relation to each other. The method for synthesizing compounds of formula (6) and formula (7) comprises the steps of resolving the compound of formula (5), octanol or pentanol, and 4-dimethylamino pyrimidium paratoluenesulfonate (DPTS), and then 1,3-dicyclohexylcarbodiimide (DCC) was added to be reacted for 24 hours.

The result of scanning electron microscopic analysis on such supramolecules confirmed that the supramolecules are regular cylindrical structures of nanometer- or smaller size.

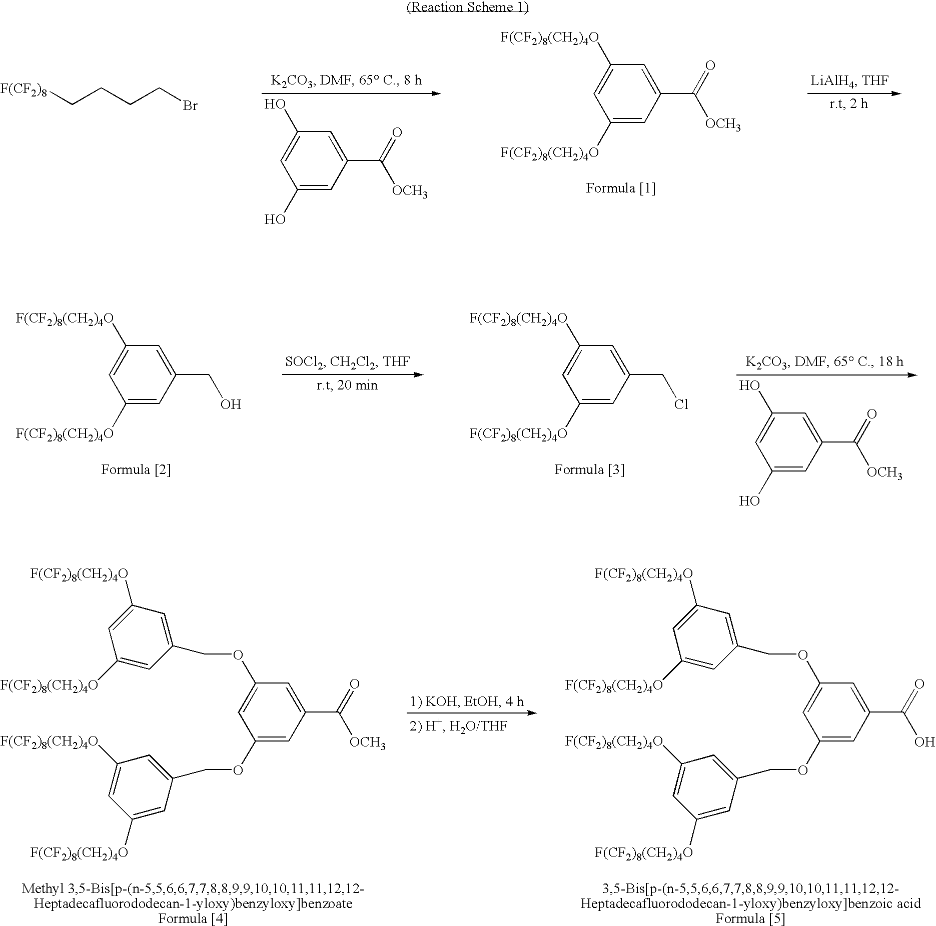

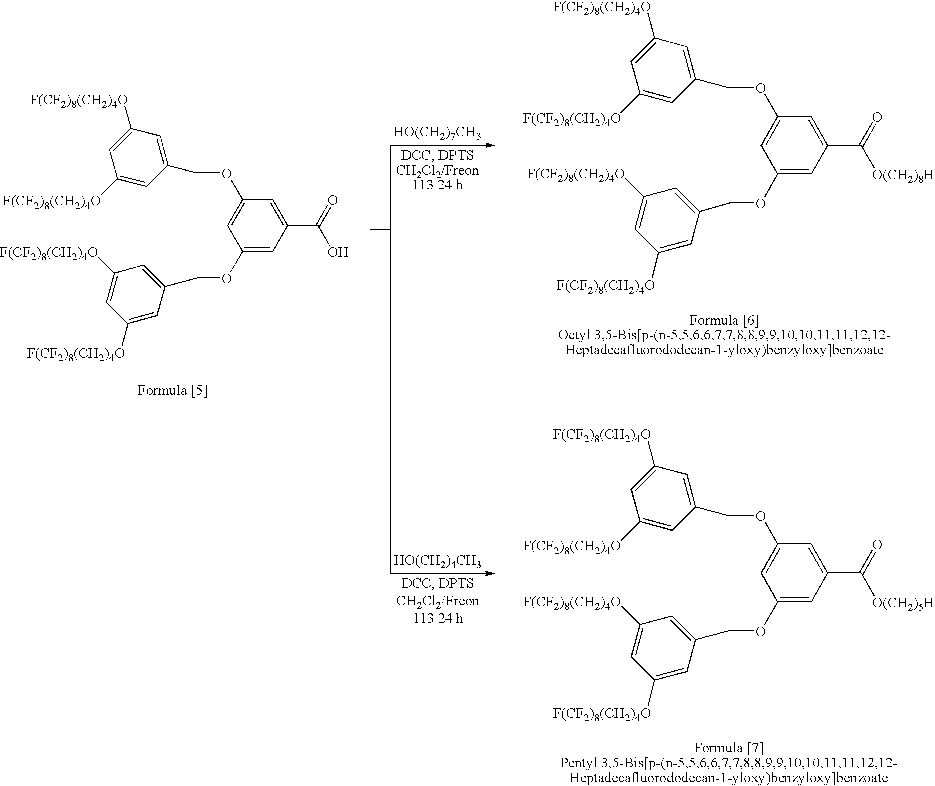

### Example 2

### Modification of Substrate Surface

In this example, a silicon wafer was used as a substrate. If necessary, metal, non-metal or other thin films can be formed on the substrate surface.

### Example 3

### Formation of Thin Film of Supramolecules

The supramolecules of formula (6) and formula (7) were dissolved in a organic solvent such as toluene, chloroform, benzene, tetrahydrofuran (THF), ethyl acetate, etc. in concentration of about 1 wt %. In this example, the spin-coating was performed at 2,000-4,000 rpm for 10-40 second to form a thin film of supramolecules.

### Example 4

### Annealing

Even though the supramolecule of formula (6) or formula (7) forms a self-assembly at around 30° C., the thin film of supramolecules was heated to 70° C. at 2° C./min and then cooled at 2° C./min slowly, to form regular microstructures for sufficient transfer. With such annealing treatment, the supramolecule of formula (6) or formula (7) formed regular microstructures by self-assembly at around 30° C. (FIG. 2b).

The supramolecules used in the present invention are self-assembled at around 30° C., which can vary according to the type of supramolecule(s) employed.

### Example 5

### UV etching

UV was applied to the microstructures obtained from the Example 4 using a UV lamp having a wavelength of 254 nm, for about 10˜30 minutes. The hole shaped nanopattern was formed by decomposing the central part in which carbon chains are gathered (FIG. 2c). Residues decomposed by UV were removed using tertiary distilled water.

### Example 6

### Deposition of Metal Catalyst

To form the thin layer of metal catalyst (Fe, Ni, Co, or an alloy thereof) for CNT synthesis using the nanopattern of supramolecules obtained by the Example 5 as a mask, the metal catalyst was deposited on the surface of silicon wafer using methods such as sputtering, thermal deposition, ion-beam deposition or atomic layer deposition (ALD) (FIG. 2d).

### Example 7

### Lift-Off

The pattern of supramolecules was dissolved by using an organic solvent such as toluene, chloroform, benzene, tetrahydrofuran (THF), ethyl acetate, etc., following which the supramolecule pattern and the deposited metal catalyst were removed completely, so that the metal catalyst nanoarray could be fabricated (FIG. 2e).

### Example 8

### Fabrication of CNT Array

Reacting gas such as C₂H₂, CH₄, C₂H₄, C₂H₆, CO, etc. was supplied into a chamber and power having high frequency was applied to the both electrodes to cause glow electric discharge, thereby vertically synthesizing and growing CNT on the metal catalyst nanoarray on a substrate formed from the Example 7. The synthesized CNT formed a CNT array on the substrate by the regular arrangement of fixed metal catalyst.

Moreover, the vertically grown CNT can be treated with plasma by a method similar to the described in Huang, S. et al., J. Phys. Chem. B, 106:3543, 2002, with a carboxyl group being introduced to the CNT by removing the cap of the end portion. Various bioreceptors then can be chemically fixed to the CNT.

### Example 9

### Fabrication of CNT-Bionanoarray

For attaching bioreceptors to the CNT array fabricated according to Example 8, the method of binding by applying a charge of polarity opposite to the net charge of the bioreceptor to the CNT (KR 2003-0014997A) or using a binding aid can be used (FIG. 2f). The preferred binding aid includes a chemical substance having an aldehyde, amine or imine group attached to a carbon group end.

Furthermore, a biochip can be fabricated by fixing a bioreceptor having an amine group (NH₂), by means of an amide bond, to the end of CNT array having an exposed carboxyl group formed as in Example 8. For this method, it is preferred that EDC(1-ethyl-3-(3-dimethylamini-propyl)carbodiimide hydrochloride) is used as a coupling agent and NHS(N-hydroxysuccinimide), NHSS(N-hydroxysulfosuccinimide) is used as a coupling aid.

As described above, the several nanometer- or smaller size pattern can be simply fabricated by a method comprising several steps according to the present invention, and the thin film structure can be easily formed due to the simple directional control of the microstructure. The nanopattern according to the present invention can be broadly used in the field of bioelements such as recording material with high density, templates for fabricating CNT and metal nanowire, protein chips, DNA chips, biosensors, etc., masks for forming new nanopatterns, and porous electrodes of dry cells. Furthermore, it can be used in the development of the material for separation membranes and coating elements for anti-reflecting applications.

1. A method for forming nanometer- or smaller sized pattern, which comprises the steps of:
(a) forming a thin film of supramolecules inducing self-assembly on a substrate;
(b) self-assembling the supramolecules by annealing to form a cylindrical shaped regular structure; and
(c) applying UV to the cylindrical shaped structure formed by self-assembly of the supramolecules and then decomposing a central part in which carbon chains are gathered, thereby forming a hole shaped nanopattern of supramolecules.

2. A method for forming nanopattern on a substrate, which comprises the step of etching the substrate using a nanopattern of supramolecules formed by the method of claim 1 as a mask.

3. The method of claim 1, wherein the supramolecules are disc-shaped or dendrimer fan-shaped supramolecules.

4. The method of claim 3, wherein the supramolecules are compounds of the following formula (6) or formula (7):

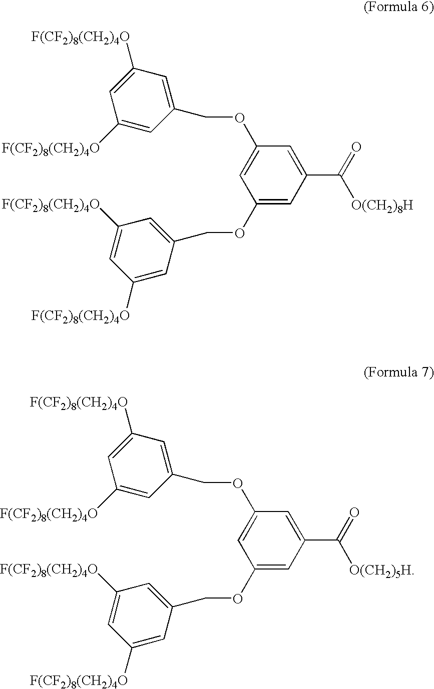

5. The method of claim 1, wherein the step (b) is performed by heating the supramolecule above its liquid crystal phase transition temperature and then cooling slowly.

6. The method of claim 1, which additionally comprises a step (d) of removing residues decomposed by UV.

7. A method of fabricating a bio nanoarray, which comprises the step of attaching a bioreceptor to a groove-shaped substrate nanopattern fabricated by the method of claim 2.

8. A method for fabricating a carbon nanotube(CNT) nanoarray, which comprises the steps of:
(a) forming a thin film layer of metal catalyst selected from the group consisting of Fe, Ni, Co, and alloys thereof, for growing CNT vertically on a nanopattern of supramolecules formed by the method of claim 1;
(b) performing a lift-off process using a solvent which is capable of dissolving the supramolecules;
(c) forming a metal catalyst array by removing residues after the lift-off process; and
(d) synthesizing CNT vertically on the formed metal catalyst array.

9. The method of claim 8, which additionally comprises the step of introducing carboxyl group functionality to a CNT end by plasma treatment on the end of a CNT in a CNT nanoarray synthesized vertically, and then removing a cap portion of the CNT.

10. A method for fabricating a CNT bio nanoarray, which comprises attaching a bioreceptor selected from the group consisting of proteins, peptides, amino acids, DNA, PNA, enzymatic substrates, ligands, cofactors, carbohydrates, lipids, oligonucleotides, and RNA to a CNT of a CNT nanoarray fabricated by the method of claim 8.

11. The method of claim 10, wherein a bio receptor is attached to the CNT by applying an electric field.

12. The method of claim 11, wherein a charge of a polarity opposite to the net charge of the bioreceptor is applied to the CNT.

13. The method of claim 10, wherein the bioreceptor is attached to the CNT using a binding aid.

14. The method of claim 13, wherein the binding aid includes a chemical substance having an aldehyde, amine or imine group attached to a terminal carbon group.

15. A method for fabricating a CNT-bionanoarray, which comprises binding a bioreceptor having an amine group (NH₂) to an end carboxyl group of a CNT of a CNT nanoarray fabricated by the method of claim 9.

16. The method of claim 15, which comprises using a coupling agent and a coupling aid for inducing an amide bond in said binding.

17. A method of detecting reaction between biomaterials and bioreceptors, which comprises using a CNT-bio nanoarray fabricated by the method of claim 10.

18. A method for fabricating a nanopattern of magnetic metal thin film for providing recording material with high density, which comprises the steps of:
(a) forming a thin film of supramolecules inducing self-assembly on a substrate;
(b) self-assembling the supramolecules by annealing to form a cylindrical shaped regular structure;
(c) applying UV to the cylindrical shaped regular structure formed by self-assembly of the supramolecules and then decomposing a central part in which carbon chains are gathered;
(d) forming a magnetic metal thin layer on the pattern of supramolecules;
(e) performing a lift-off process using a solvent which is capable of dissolving the pattern of supramolecules; and
(f) removing residues after the lift-off process.

19. The method of claim 18, wherein the magnetic metal includes a metal selected from the group consisting of Fe, Ni, Co, Cr, Pt, and alloysF thereof.
